(19) United States
(12) Patent Application Publication
(10) Pub. No.: US 2008/0236750 A1
(43) Pub. Date: Oct. 2, 2008

(54) PLASMA PROCESSING APPARATUS

(75) Inventor: Chishio KOSHIMIZU, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/055,839

(22) Filed: Mar. 26, 2008

Related U.S. Application Data
(60) Provisional application No. 60/940,089, filed on May 25, 2007.

(30) Foreign Application Priority Data
Mar. 27, 2007 (JP) 2007-081844

(51) Int. Cl. C23C 16/505; C23F 1/02

(52) U.S. Cl. 156/345.38; 118/723 VE

(57) ABSTRACT

A plasma processing apparatus includes a processing chamber, a first electrode and a second electrode attached to the processing chamber via an insulator. To generate a plasma of a processing gas in the processing space, a high frequency power supply unit applies to the first electrode a high frequency power having a predetermined high frequency. Further, to control energy of incident ions on the first and the second electrode from the plasma, a first low frequency power supply unit applies to the first electrode a first low frequency power having the frequency lower than the frequency of the high frequency power, and a second low frequency power supply unit applies to the second electrode a second low frequency power having the frequency lower than the frequency of the high frequency power.

### FIELD OF THE INVENTION

The present invention relates to a plasma processing apparatus for performing a required microprocessing on a target substrate by using a plasma; and, more particularly, to a plasma processing apparatus that generate a plasma by applying to an electrode for supporting a substrate in a processing chamber.

### BACKGROUND OF THE INVENTION

In a manufacturing process of a semiconductor device or an FPD (flat panel display), a plasma is often used in such processes as etching, deposition, oxidation, ashing, sputtering, in order to allow a processing gas to react efficiently at a relatively low temperature. Conventionally, a capacitively coupled plasma processing apparatus is mainly used as a single-wafer plasma processing apparatus, especially as a plasma etching apparatus.

In general, in the capacitively coupled plasma processing apparatus, an upper and a lower electrode are disposed in parallel with each other in a vacuum processing chamber, and a target substrate (e.g., a semiconductor wafer, a glass substrate or the like) is mounted on the lower electrode. In that state, a high frequency voltage is applied to one of the upper and the lower electrode, and electrons are accelerated by an electric field formed between the electrodes by the application of the high frequency voltage. Ionization by collision between the electrons and a processing gas generates a plasma, and a required microprocessing, e.g., etching, is performed on a substrate surface by radicals and/or ions in the plasma.

In a lower electrode cathode type capacitively coupled plasma processing apparatus that a high frequency power is applied to an electrode supporting a substrate, i.e., a lower electrode, ions in the plasma are introduced to the substrate substantially in perpendicular thereto by a self-bias voltage generated at the lower electrode, so that anisotropic etching having good directionality can be carried out.

Recently, there is widely used a lower electrode dual frequency application type in which a high frequency power having a high frequency greater than 13.56 MHz for plasma generation and a low frequency power having a low frequency smaller than or equal to 13.56 MHz for ion attraction are superposedly applied to the lower electrode. In a conventional lower electrode dual frequency application type, there is employed a configuration that an upper electrode is grounded as an anode electrode. In such a case, the upper electrode is directly integratedly attached to a ceiling of the processing chamber, or the ceiling of the processing chamber serves as the upper electrode (see, e.g., Japanese Patent Laid-open Application No. 2000-156370).

In general, in the plasma processing apparatus, gaseous reaction products or reaction by-products generated during the plasma processing are adhered to parts in the processing chamber, especially to surfaces of members facing the plasma, e.g., the upper electrode or a sidewall of the processing chamber and solidified as deposits. Further, when the upper electrode is oxidized by the plasma, an oxide film is formed on the electrode surface. For example, when the upper electrode is made of silicon (Si), an SiO₂ film is formed on the electrode surface. If the deposits or the silicon oxidation adhered to the surfaces of the members facing the plasma are separated by peeling off a film or the like, the deposits become particles, thereby deteriorating a production yield. To that end, the deposits are removed from the members in the processing chamber by performing a cleaning process regularly or when necessary.

However, in a conventional capacitively coupled plasma processing apparatus employing the lower electrode dual frequency application type, a self-bias is not generated on the upper electrode of a ground potential, so that energy of incident ions colliding therewith is low. Therefore, the sputtering effect becomes weak, and a large amount of deposits or an oxide film can be easily adhered to the upper electrode. As a result, stability or reproducibility of the processing deteriorates. Moreover, although plasma cleaning is widely used in a cleaning process, it is difficult to effectively remove the deposits from a sidewall of the chamber in a short period of time.

### SUMMARY OF THE INVENTION

In view of the above, the present invention provides a capacitively coupled plasma processing apparatus capable of improving the stability or the reproducibility of the processing by effectively preventing deposits or an oxide film from being adhered to an electrode for supporting a substrate or to a facing electrode of the opposite side.

The present invention also provides a capacitively coupled plasma processing apparatus in which a plasma potential or a density of a plasma can be controlled from a facing electrode side.

In accordance with a first aspect of the present invention, there is provided a plasma processing apparatus comprising: a vacuum evacuable processing chamber; a first electrode, attached to the processing chamber via an insulator, for supporting a substrate to be processed in the processing chamber; a second electrode, attached to the processing chamber via an insulator, facing the first electrode in parallel in the processing chamber; and a processing gas supply unit for supplying a processing gas to a processing space between the first electrode and the second electrode.

The processing apparatus further comprises a high frequency power supply unit for applying to the first electrode a high frequency power to generate a plasma of the processing gas in the processing space; a first low frequency power supply unit for applying to the first electrode a first low frequency power to control energy of incident ions on the first electrode from the plasma, the frequency of the first low frequency power being lower than the frequency of the high frequency power; and a second low frequency power supply unit for applying to the second electrode a second low frequency power to control energy of incident ions on the second electrode from the plasma, the frequency of the second low frequency power being lower than the frequency of the first low frequency power.

With such configuration, the plasma generation or the plasma density is controlled mainly by the high frequency power applied to the first electrode (generally, the lower electrode); the energy of incident ions on the first electrode is controlled mainly by the first low frequency power applied to the first electrode; and the energy of incident ions on the second electrode is controlled mainly by the second low frequency power applied to the second electrode (generally, the upper electrode).

Thus, the optimum characteristics of the plasma density and the ion energy can be simultaneously obtained by selecting appropriate frequencies and powers of the high frequency power and the first and the second low frequency power. Especially, the deposits or the oxide film can be prevented from being adhered to the second electrode by increasing the energy of incident ions on the second electrode.

It is preferable that the first low frequency power has a frequency higher than an ion plasma frequency and the second low frequency power has a frequency lower than the ion plasma frequency. In this case, the ions in the plasma are incident on the first electrode by accelerating the ions by a DC electric field of a sheath in accordance with a self-bias voltage generated in the first electrode, and also are incident on the second electrode at half cycle intervals in response to an RF electric field of the frequency of the second low frequency power.

In accordance with a second aspect of the present invention, there is provided a plasma processing apparatus comprising: a vacuum evacuable processing chamber; a first electrode, attached to the processing chamber via an insulator, for supporting a substrate to be processed in the processing chamber; a second electrode, attached to the processing chamber via an insulator, facing the first electrode in parallel in the processing chamber; and a processing gas supply unit for supplying a required processing gas to a processing space between the first electrode and the second electrode.

In addition, the plasma processing apparatus further comprises a high frequency power supply unit for applying to the first electrode a high frequency power to generate a plasma of the processing gas in the processing space; a first low frequency power supply unit for applying to the first electrode a first low frequency power to control energy of incident ions on the first electrode from the plasma, the frequency of the first low frequency power being lower than the frequency of the high frequency power; and a second low frequency power supply unit for applying to the second electrode a second low frequency power to control energy of incident ions the second electrode from the plasma, the frequency of the second low frequency power being equaling to the frequency of the first low frequency power.

With such configuration, the efficiency of the low frequency power supply unit can be achieved by equalizing the frequency of the first low frequency power applied to the first electrode with that of the second low frequency power applied to the second electrode.

It is preferable that the first and the second low frequency power supply unit share a common low frequency power supply. Further, the first and the second low frequency power supply unit may comprise a first and a second amplifier for amplifying the first and the second low frequency power, respectively.

Moreover, the first low frequency power supply unit may comprise a first matching circuit for matching an impedance of the low frequency power supply with an impedance of the first electrode, and the second low frequency power supply unit comprises a second matching circuit for matching an impedance of the low frequency power supply with an impedance of the second electrode.

A phase control unit may be provided for varying a relative phase difference between the first low frequency power and the second low frequency power. In that case, the plasma potential can be variably controlled by varying the phase difference between the first and the second low frequency power.

For example, when a plasma cleaning for removing a deposited film adhered to an inner wall of the processing chamber is performed, the phase difference may be set to a maximum value or a value close thereto. Therefore, the plasma potential is constantly high, and the ion sputtering on the inner wall of the chamber is enhanced. As a result, the film deposited on the inner wall of the chamber can be effectively removed in a short period of time.

In accordance with a third aspect of the present invention, there is provided a plasma processing apparatus comprising: a vacuum evacuable processing chamber; a first electrode, attached to the processing chamber via an insulator, for supporting a substrate to be processed in the processing chamber; a second electrode, attached to the processing chamber via an insulator, facing the first electrode in parallel in the processing chamber; and a processing gas supply unit for supplying a required processing gas to a processing space between the first electrode and the second electrode.

In addition, the plasma processing apparatus comprises a high frequency power supply unit for applying to the first electrode a high frequency power to generate a plasma of the processing gas in the processing space; a first low frequency power supply unit for applying to the first electrode a first low frequency power to control energy of incident ions the first electrode from the plasma, the frequency of the first low frequency power being lower than the frequency of the high frequency power; and a second low frequency power supply unit for applying to the second electrode a second low frequency power to control energy of incident ions on the second electrode from the plasma, the frequency of the second low frequency power being higher than the frequency of the first lower frequency power and lower than the frequency of the high frequency power.

With such configuration, the frequency of the second low frequency power is higher, so that the self-bias voltage generated in the second electrode is reduced. Accordingly, the effect of the ion sputtering on the second electrode becomes weak, whereas the contribution of the second low frequency power to the plasma generation increases, thereby improving the plasma density.

In accordance with a fourth aspect of the present invention, there is provided a plasma processing apparatus comprising: a vacuum evacuable processing chamber; a first electrode, attached to the processing chamber via an insulator, for supporting a substrate to be processed in the processing chamber; a second electrode, attached to the processing chamber via an insulator, facing the first electrode in parallel in the processing chamber; and a processing gas supply unit for supplying a processing gas to a processing space between the first electrode and the second electrode.

The plasma processing apparatus further comprises a first high frequency power supply unit for applying to the first electrode a first high frequency power to generate a plasma of the processing gas in the processing space; a low frequency power supply unit for applying to the first electrode a low frequency power to control energy of incident ions on the first electrode from the plasma, the frequency of the low frequency power being lower than the frequency of the first high frequency power; and a second high frequency power supply unit for applying to the second electrode a second high frequency power to control energy of incident ions on the second electrode from the plasma, the frequency of the second high frequency power being equaling to the frequency of the first high frequency power.

With such configuration, the frequency of the second high frequency power applied to the second electrode is further higher than that of the second low frequency power described in the configuration of the third aspect of the present invention. Therefore, the effect of the ion sputtering on the second electrode becomes weaker, whereas the contribution of the second high frequency power to the plasma generation further increases compared to the configuration of the third aspect of the present invention.

In accordance with a fifth aspect of the present invention, there is provided a plasma processing apparatus comprising: a vacuum evacuable processing chamber; a first electrode, attached to the processing chamber via an insulator, for supporting a substrate to be processed in the processing chamber; a second electrode, attached to the processing chamber via an insulator, facing the first electrode in parallel in the processing chamber; and a processing gas supply unit for supplying a processing gas to a processing space between the first electrode and the second electrode.

In addition, the plasma processing apparatus further comprises a high frequency power supply unit for applying to the first electrode a high frequency power to generate a plasma of the processing gas in the processing space and a low frequency power supply unit for applying to the second electrode a low frequency power to control energy of incident ions on the second electrode from the plasma, the frequency of the low frequency power being lower than the frequency of the high frequency power.

In such configuration, the first high frequency power applied to the first electrode and the low frequency power applied to the second electrode can produce similar effects to those of the high frequency power and the second low frequency power in the plasma processing apparatus in accordance with the first aspect of the present invention.

In accordance with the above configurations and operations of the plasma processing apparatus of the present invention, the stability or the reproducibility of the processing can be improved by effectively preventing deposits or an oxide film from being adhered to an electrode for supporting a substrate or to a facing electrode of the opposite side. In addition, a plasma potential or a plasma density can be controlled from the facing electrode side.

### BRIEF DESCRIPTION OF THE DRAWINGS

The objects and features of the present invention will become apparent from the following description of embodiments, given in conjunction with the accompanying drawings, in which:

FIG. 1 shows a vertical cross sectional view of a configuration of a capacitively coupled plasma etching apparatus in accordance with a first embodiment of the present invention;

FIG. 2 explains an operation of a lower electrode dual frequency/upper electrode single frequency application type in the plasma etching apparatus of FIG. 1;

FIG. 3 provides a vertical cross sectional view of a configuration of a capacitively coupled plasma etching apparatus in accordance with a second embodiment of the present invention;

FIG. 4 illustrates an equivalent circuit for a portion related to a self-bias voltage and a plasma potential in the plasma etching apparatus of FIG. 3;

FIG. 5 explains a case where a phase difference between two low frequency powers is set to zero (in-phase) in the equivalent circuit of FIG. 4;

FIG. 6 describes a case where a phase difference between the two low frequency powers is set to a maximum value (anti-phase) in the equivalent circuit of FIG. 4;

FIG. 7 presents a cross sectional view of an example of an etching process to which the plasma etching apparatus of FIG. 3 can be applied;

FIG. 8 represents a vertical cross sectional view of a configuration of a capacitively coupled plasma etching apparatus in accordance with a first modification of the second embodiment; and

FIG. 9 offers a vertical cross sectional view of a configuration of a capacitively coupled plasma etching apparatus in accordance with a second modification of the second embodiment.

### DETAILED DESCRIPTION OF THE EMBODIMENT

The embodiments of the present invention will be described with reference to the accompanying drawings which form a part hereof.

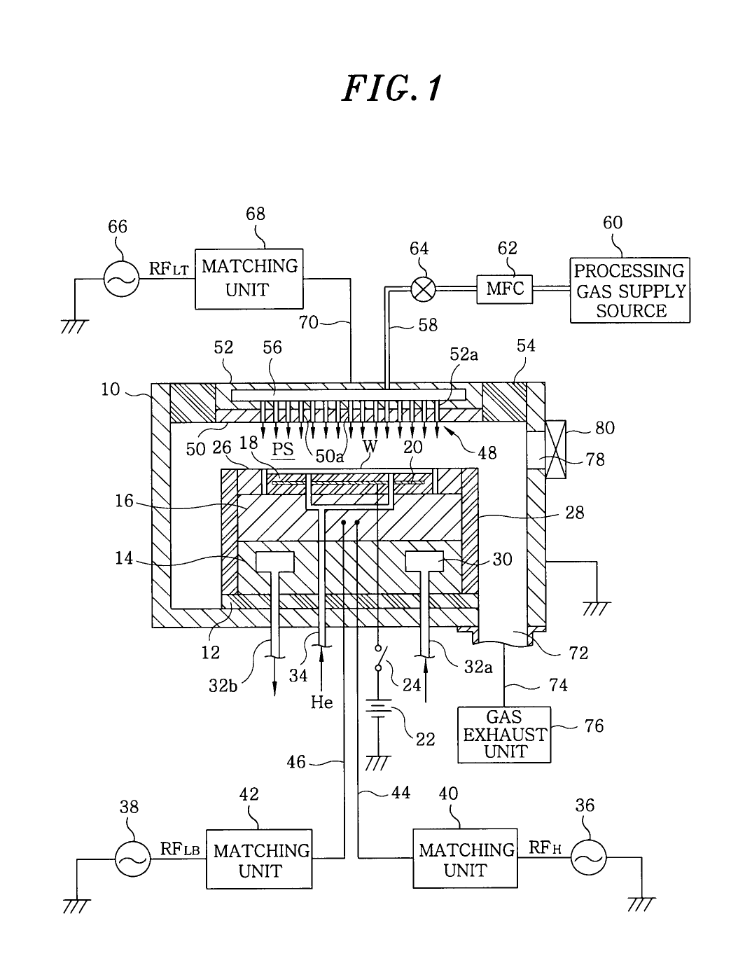

FIG. 1 shows a configuration of a plasma etching apparatus in accordance with a first embodiment of the present invention. This plasma etching apparatus is constructed as a lower electrode dual frequency/upper electrode single frequency application type capacitively coupled (parallel plate type) plasma etching apparatus, and includes a cylindrical chamber (processing chamber) 10 made of a metal such as aluminum, stainless steel or the like. The chamber 10 is frame-grounded.

A cylindrical susceptor supporting table 14 is provided on a bottom surface of the chamber 10 via an insulating plate 12 such as ceramic or the like. Further, a susceptor 16 made of, e.g., aluminum, is disposed on the susceptor supporting table 14. The susceptor 16 serves as a lower electrode, and mounts thereon a target substrate, e.g., a semiconductor wafer W.

An electrostatic chuck 18 for attracting and holding the semiconductor wafer W by electrostatic attraction force is provided on a top surface of the susceptor 16. The electrostatic chuck 18 is formed by embedding an electrode 20 made of a conductive film in a pair of insulation layers or insulation sheets. A DC power supply 22 is electrically connected to the electrode 20 via a switch 24. The semiconductor wafer W can be attracted and held on the electrostatic chuck 18 by Coulomb force generated by a DC voltage applied from the DC power supply 22. Besides, a focus ring 26 for improving in-plane etching uniformity is provided on the top surface of the susceptor 16 to surround the electrostatic chuck 18, the focus ring 26 being made of, e.g., silicon. A cylindrical inner wall member 28 made of, e.g., quartz, is attached to side surfaces of the susceptor 16 and the susceptor supporting table 14.

A coolant reservoir or a coolant passageway 30 extending in, e.g., a circumferential direction, is provided inside the susceptor supporting table 14. A coolant maintained at a predetermined temperature, e.g., cooling water, supplied from a chiller unit (not shown) located outside via lines 32a and 32b is circulated in the coolant passageway 30. A proceeding temperature of the semiconductor wafer W on the susceptor 16 can be controlled by the temperature of the coolant. Moreover, a thermally conductive gas, e.g., He gas, is supplied from a thermally conductive gas supply unit (not illustrated) to a space between the electrostatic chuck 18 and the semiconductor wafer W via a gas supply line 34.

A lower electrode high frequency power supply 36 and a lower electrode low frequency power supply 38 are electrically connected to the susceptor 16 via lower electrode matching units 40 and 42 and lower electrode power supply rods 44 and 46. The lower electrode high frequency power supply 36 outputs a predetermined lower electrode high frequency power RF_{H} having a predetermined frequency, e.g., 40 MHz, for generating a plasma. Meanwhile, the lower electrode low frequency power supply 38 outputs a predetermined lower electrode low frequency power RF_{LB} having a predetermined frequency, e.g., 3.2 MHz, for attracting ions to the semiconductor wafer W on the susceptor 16.

An upper electrode 48 is provided in parallel with the susceptor 16 above the susceptor 16. Further, the upper electrode 48 includes: an electrode plate 50 made of, e.g., a semiconductor material such as Si, SiC or the like, having a plurality of gas injection openings 50a; and an electrode support 52 made of a conductive material, e.g., aluminum having an alumite treated surface, for attachably/detachably supporting the electrode plate 50. Furthermore, the upper electrode 48 is attached to an upper portion of the chamber 10 via a ring-shaped insulator 54. A space between the electrode plate 48 and the susceptor 16 is set as a plasma generation space or a plasma processing space PS. The ring-shaped insulator 54 is made of, e.g., alumina (Al₂O₃), and airtightly seals a gap between an outer peripheral surface of the upper electrode 48 and the sidewall of the chamber 10, thereby supporting the upper electrode 48 physically in a non-grounded state.

The electrode support 52 has therein a gas buffer chamber 56, and also has on its bottom surface a plurality of gas ventholes 52a extending from the gas buffer chamber 56 to communicate with the gas injection openings 50a of the electrode plate 50. The gas buffer chamber 56 is connected to a processing gas supply source 60 via a gas supply line 58. Moreover, a mass flow controller (MFC) 62 and an opening/closing valve 64 are provided in the gas supply line 58. When a predetermined processing gas from the processing gas supply source 60 is introduced into the gas buffer chamber 56, the processing gas is injected in a shower shape from the gas injection openings 50a of the electrode plate 50 toward the semiconductor wafer W on the susceptor 16 in the processing space PS. Namely, the upper electrode 48 serves as a shower head for supplying the processing gas into the processing space PS.

An upper electrode low frequency power supply 66 is electrically connected to the upper electrode 48 via an upper electrode matching unit 68 and an upper electrode power supply rod 70. Moreover, the upper electrode lower electrode frequency power supply 66 outputs a predetermined upper electrode low frequency power RF_{LT} having a predetermined frequency of, e.g., 380 kHz, for ion attraction to the upper electrode 48.

A ring-shaped space formed by the sidewall of the chamber 10, the susceptor supporting table 14 and the susceptor 16 serves as an exhaust space. A gas exhaust port 72 is provided at a bottom portion of the exhaust space, and a gas exhaust unit 76 is connected to the gas exhaust port 72 via a gas exhaust line 74. The gas exhaust unit 76 has a vacuum pump such as a turbo-molecular pump or the like, so that an inner space of the chamber 10, especially a processing space PS, can be depressurized to a required vacuum level. Attached to a sidewall of the chamber 10 is a gate valve 80 for opening and closing a loading/unloading port 78 of the semiconductor wafer W.

In this plasma processing apparatus, in order to perform the etching, the semiconductor wafer W to be processed is loaded into the chamber 10 while opening the gate valve 80, and then is mounted on the electrostatic chuck 18. Next, a predetermined processing gas, i.e., an etching gas (generally, a gaseous mixture), is introduced into the chamber 10 at a predetermined flow rate and flow rate ratio from the processing gas supply unit 60, and a pressure inside the chamber 10 is set to be at a predetermined level by vacuum evacuation using the gas exhaust unit 76. Then, the predetermined lower electrode high frequency power RF_{H} (40 MHz) from the lower electrode high frequency power supply 36 and the predetermined lower electrode low frequency power RF_{LB} (3.2 MHz) from the lower electrode low frequency power supply 38 are superposedly applied to the susceptor (the lower electrode) 16, and the predetermined upper electrode low frequency power RF_{LT} (380 KHz) from the upper electrode low frequency power supply 66 is applied to the upper electrode 48.

Thereafter, the switch 24 is turned on, and the thermally conductive gas (He gas) is confined by electrostatic attraction force in a contact interface between the electrostatic chuck 18 and the semiconductor wafer W. The etching gas discharged through the shower head (upper electrode) 48 is converted into a plasma between both electrodes 16 and 46 by a high frequency discharge, and the film formed on the main surface of the semiconductor wafer W is etched by radicals or ions generated in the plasma.

In this plasma etching, most of volatile reaction products generated on the main surface of the semiconductor wafer W are exhausted to the outside of the gas exhaust port 72. However, a part of the reaction products are adhered as deposits to the electrode plate 50 of the upper electrode 48, the sidewall of the chamber 10 or the like, thereby forming a coating film or a deposited film. Besides, when the electrode plate 50 is oxidized under the plasma, an oxide film (e.g., SiO₂ film) is formed on the electrode surface.

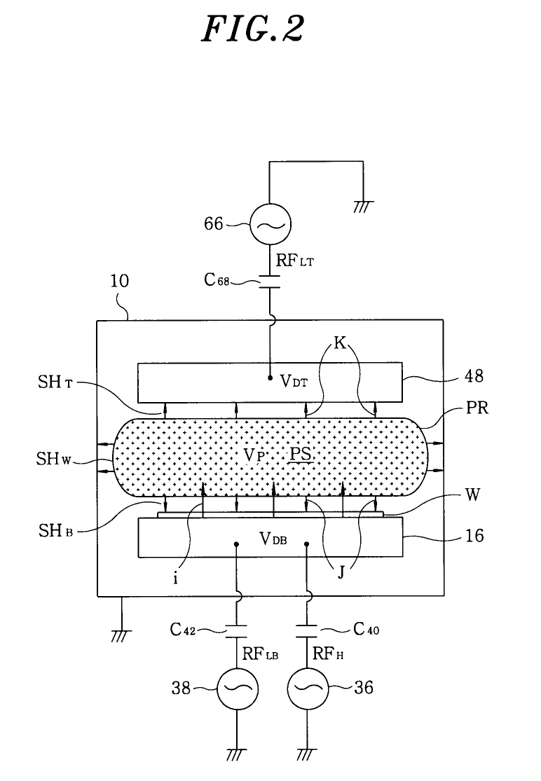

FIG. 2 explains an operation of the lower electrode dual frequency/upper electrode single frequency application type in this plasma etching apparatus. In FIG. 2, C₄₀, C₄₂ and C₆₈ indicate blocking capacitors provided in the matching units 40, 42 and 68, respectively.

When the plasma processing is being performed, the lower electrode high frequency RF_{H} (40 MHz) from the high frequency power supply 36 is applied to the susceptor 16, and a high frequency current i is supplied from the susceptor 16 to the processing space PS. Accordingly, molecules and atoms of a processing gas are dissociated and ionized, thereby generating a plasma PR. When radicals in the plasma PR are diffused and reach the surface of the semiconductor wafer W on the susceptor 16, the radicals react with atoms of a material to be processed, and the reaction products are volatilized.

In addition, the lower electrode low frequency power RF_{LB} (3.2 MHz) from the lower electrode low frequency power supply 38 is applied the susceptor 16, so that a self-bias voltage V_{DB} in accordance with an amplitude of an applied voltage of the lower electrode low frequency power RF_{LB} is generated on the susceptor 16. Although positive ions in the plasma PR cannot respond to the RF electric field of the frequency (3.2 MHz) of the lower electrode low frequency RF_{LB} which is higher than the ion plasma frequency (generally, from 1 MHz to 2 MHz), they are accelerated by an electric field or a DC voltage difference generated in a sheath SH_{B} between the susceptor 16 and the plasma PR, thereby making collision with the surface of the semiconductor wafer W (as indicated by an arrow J in FIG. 2). Accordingly, a surface reaction or a separation of the reaction products is facilitated. Moreover, secondary electrons generated by the ion impact are bombarded into the plasma PR while being accelerated by the DC electric field in the sheath SH_{B}.

Meanwhile, the upper electrode low frequency power RF_{LT} (380 kHz) from the upper electrode low frequency power supply 66 is applied to the upper electrode 48. Accordingly, a self-bias voltage V_{DT} in accordance with an amplitude of an applied voltage of the upper electrode low frequency power RF_{LT} is generated in the upper electrode 48. The positive ions in the plasma PR collide with the surface of the upper electrode 48 at half cycle intervals (as indicated by an arrow K in FIG. 2) in response to the electric field of the frequency (380 kHz) of the upper electrode frequency power RF_{LT} which is set to be lower than the ion plasma frequency, thereby sputtering (removing) the oxide film or the deposited film on the surface of the upper electrode 48.

Further, secondary electrons generated by the collision between the positive ions and the surface of the upper electrode 48 are accelerated by a DC electric field in a sheath SH_{T} between the upper electrode 48 and the plasma PR and bombarded into the plasma PR. In addition, an electron current is supplied from the upper electrode 48 to the plasma PR at half cycle intervals.

As described above, in the lower electrode dual frequency/upper electrode single frequency application type of this embodiment, the plasma PR is generated and maintained by the high frequency discharge between the electrodes 16 and 48 in accordance with the lower electrode high frequency power RF_{H} (40 MHz). However, the upper electrode low frequency power RF_{LT} (380 kHz) and the lower electrode low frequency power RF_{LB} (3.2 MHz) also contribute to the improvement of the plasma density. In addition, radical etching and ion assist etching are performed on the semiconductor wafer W on the susceptor 16 at rates mainly controlled by the lower electrode high frequency power RF_{H} (40 MHz) and the lower electrode low frequency power RF_{LB} (3.2 MHz). Meanwhile, sputtering is performed on the upper electrode 48 at a rate mainly controlled by the upper electrode low frequency power RF_{LT} (380 kHz), respectively.

Since the upper electrode low frequency power RF_{LT} has a low frequency (380 kHz), sufficiently high ion energy can be generated even by a relatively low power level. Therefore, a small and low-cost power supply can be used as the upper electrode low frequency power supply 66.

As described above, due to the sputtering on the upper electrode 48 during the plasma processing, the upper electrode 48 can maintain a clean surface where the adhesion of deposits or the formation of an oxide film does not occur or slightly occurs. Thus, the processing becomes stable and, also, the reproducibility of the processing is improved.

When the material of the electrode plate 50 includes Si, there is performed an operation of returning the reaction products in the form of SiF₄ to the processing space by capturing excess F radicals which attact a resist mark. The F radical capturing operation is facilitated by maintaining the electrode surface in a clean state and, hence, the selectivity can be improved.

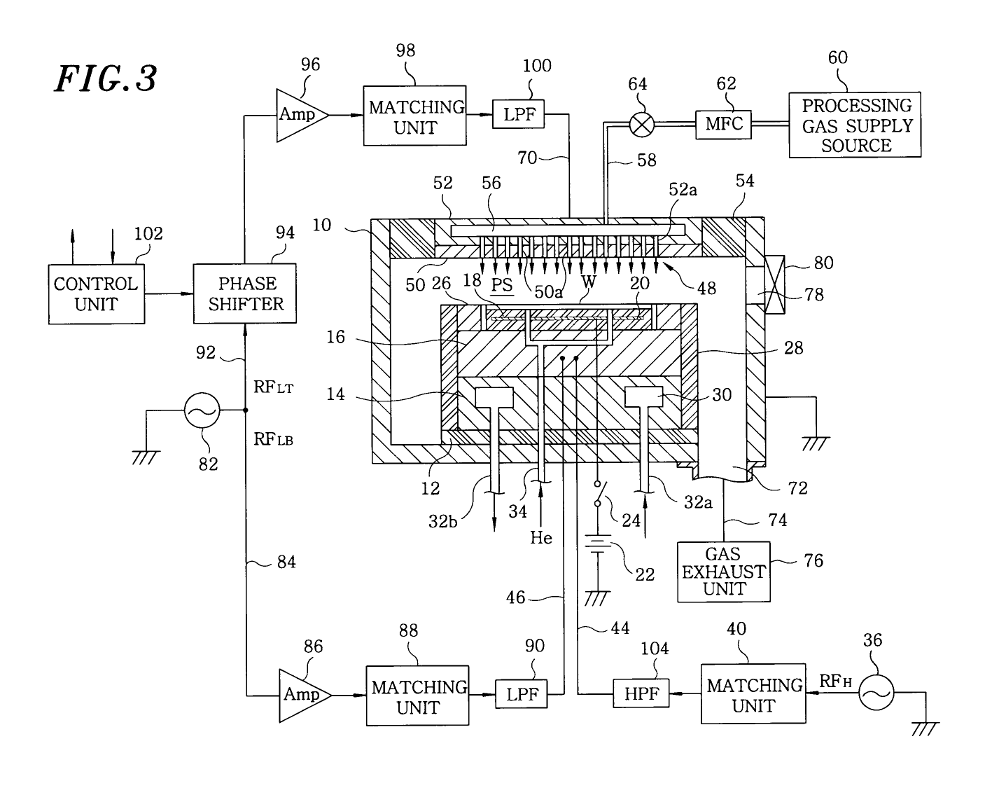

FIG. 3 provides a vertical cross sectional view of a configuration of a capacitively coupled plasma etching apparatus in accordance with a second embodiment of the present invention. Like reference numerals will be given to like parts having the same configurations or functions identical to those described in the first embodiment.

In the second embodiment employing the lower electrode dual frequency/upper electrode single frequency application type, the lower electrode low frequency power and the upper electrode low frequency power are set to have the same frequency and a phase difference between both low frequency powers can be randomly varied. The low frequency power having a predetermined frequency (e.g., 2 MHz) from a common low frequency oscillator (power supply) 82 is applied, as the lower electrode low frequency power RF_{LB}, to the susceptor 16 via a power amplifier 86 of a lower electrode low frequency power supply line 84, a lower electrode matching unit 88, a low pass filter (LPF) 90 and a lower electrode power supply rod 46, and also is applied, as the upper electrode low frequency power RF_{LT}, to the upper electrode 48 via a phase shifter 94 of an upper electrode power supply line 92, a power amplifier 96, an upper electrode matching unit 98, a low pass filter (LFP) 100 and the upper electrode power supply rod 70.

In the lower electrode low frequency power supply line 84, the power amplifier 86 amplifies the lower electrode low frequency power RF_{LB} supplied from the low frequency oscillator 82 from several mW to several hundreds of W, for example. The LPF 90 passes the lower electrode low frequency power RF_{LB} from the lower electrode matching unit 88 toward the susceptor 16, and blocks a high frequency noise (40 MHz) entering the lower electrode low frequency power supply line 84 via the susceptor 16.

In the upper electrode low frequency power supply line 92, the phase shifter 94 is formed as an RC circuit including, e.g., a volume resistor or a variable capacitor. Further, the phase shifter 94 can randomly change the phase of the upper electrode low frequency power RF_{LT} supplied from the low frequency oscillator 82 between, e.g., 0° and 180°, under the control of a control unit 102. The power amplifier 96 amplifies the upper electrode low frequency power RF_{LT} from several mW to several tens of W. The LPF 100 passes the upper electrode low frequency power RF_{LT} toward the upper electrode 48, and blocks a high frequency noise (40 MHz) entering the upper electrode low frequency power supply line 92 via the upper electrode 48 side.

In addition, a high pass filter (HPF) 104 provided in the lower electrode high frequency power supply line passes a lower electrode high frequency power RF_{H} (e.g., 40 MHZ) from the matching unit 40 toward the susceptor 16, and blocks a low frequency noise (2 MHz) entering via the susceptor 16. Each of the filters (HPF 104, LPF 90 and LPF 100) can also be used in the aforementioned first embodiment.

In this embodiment, self-bias voltages V_{DT} and V_{DB} respectively generated in the upper electrode 48 and the susceptor 16 and a potential of the plasma PR (plasma potential V_{P}) can be variably controlled by varying the phase difference between the upper electrode low frequency power RF_{LT} and the lower electrode low frequency power RF_{LB} with the use of the phase shifter 94.

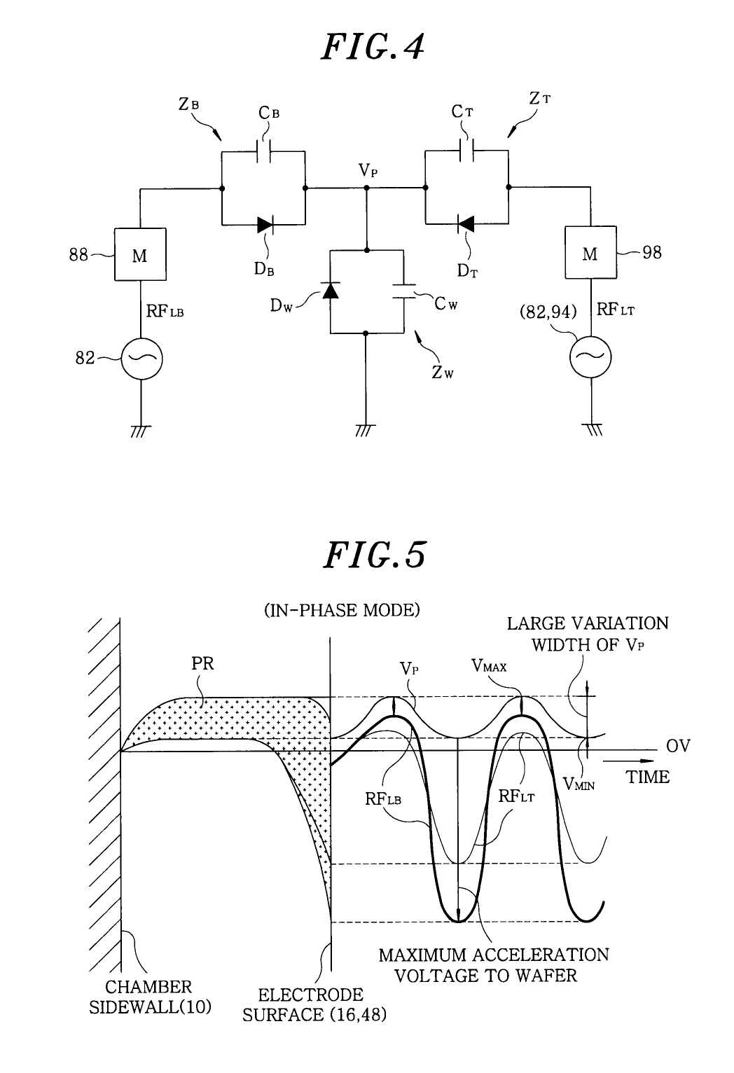

FIG. 4 illustrates an equivalent circuit for a portion related to the self-bias voltages V_{DT} and V_{DB} and the plasma potential V_{P} in this plasma etching apparatus. In this equivalent circuit, Z_{B} is an impedance of the sheath SH_{B} formed between the susceptor 16 and the plasma PR, and is indicated as a parallel circuit including a condenser C_{B} and a diode D_{B}; Z_{T} is an impedance of the sheath SH_{T} formed between the upper electrode 48 and the plasma PR, and is indicated as a parallel circuit including a condenser C_{T} and a diode D_{T}; and Z_{W} is an impedance of a sheath SH_{W} formed between the sidewall of the chamber 10 and the plasma PR, and is indicated as a parallel circuit including a condenser C_{W} and a diode D_{W}. The power supply of the equivalent circuit includes the power supply 82 for applying the lower electrode low frequency power RF_{LB} to the lower electrode 16 and the power supply 82 and 94 for applying the upper electrode low frequency power RF_{LT} to the upper electrode 48. The high frequency power supply 36 is omitted, because the effects of the high frequency power RF_{H} to the self-bias voltage or to the plasma potential are relatively small and negligible.

FIG. 5 shows the potential of each unit or the potential variation in the case where the phase difference between the upper electrode low frequency power RF_{LT} and the lower electrode low frequency power RF_{LB} is set to zero. In that case, the voltages of the low frequency powers RF_{LT} and RF_{LB} are applied in an in-phase state to the upper electrode 48 and the lower electrode 16, so that the plasma potential V_{P} oscillates greatly between a minimum value close to a ground potential (0V) and a maximum value V_{MAX} considerably higher than the minimum value.

In this case, when both of the applied voltages of the low frequency powers RF_{LT} and RF_{LB} reach positive peak values, the plasma potential V_{P} reaches its maximum value V_{MAX}, and the electron current is supplied from the plasma PR to the electrodes 48 and 16. Further, when the applied voltages of the low frequency powers RF_{LT} and RF_{LB} are negative, the plasma potential V_{P} is reduced to several tens of V. The positive ions in the plasma are accelerated by a voltage gradient in each of the sheaths SH_{T}, SH_{B} and SH_{W}, so that the positive ions collide with or are incident on the electrodes 48 and 16 and the sidewall of the chamber 10.

In the in-phase mode, the plasma potential V_{P} has a high maximum value V_{MAX} and a small minimum value V_{MIN}. Namely, there is a large difference between the maximum and the minimum of the plasma potential V_{P} and, hence, the effect of the sputtering on the sidewall of the chamber 10 decreases on the average.

FIG. 6 describes the potential of each unit or the potential variation in the case where the phase difference between the upper electrode low frequency power RF_{LT} and the lower electrode low frequency power RF_{LB} is set to a maximum value (180°). In that case, the voltages of the low frequency powers RF_{LT} and RF_{LB} are applied in an anti-phase state to the upper electrode 48 and the lower electrode 16, so that the plasma potential V_{P} oscillates slightly between a maximum value V_{MAX} and a minimum value V_{MIN} that approximates to the maximum value V_{MAX}.

In the anti-phase mode, when the each of applied voltage of the low frequency powers RF_{LT} and RF_{LB} reaches positive peak values, the plasma potential V_{P} reaches its maximum value V_{MAX}, and the current of high speed electrons is supplied from the plasma PR to the electrode 48 and 16 of positive potentials. Moreover, when the applied voltages of the low frequency powers RF_{LT} and RF_{LB} are negative, high bias voltages V_{DT} and V_{DB} can be generated in the sheath SH_{T} and SH_{B}, respectively. Accordingly, the positive ions in the plasma PR are incident on the electrode 48 and 16 with a very strong impact.

Meanwhile, the plasma potential V_{P} is constantly higher than any one of the voltages of the electrodes even when RF_{LT} has a positive voltage and when RF_{LB} has a positive voltage. Therefore, a voltage drop in the sheath SH_{W} near the sidewall of the chamber 10 is large, and thus the incident ions on the sidewall of the chamber 10 from the plasma PR have high energy. In other words, the plasma potential V_{P} has a high maximum value V_{MAX} and a high minimum value V_{MIN} and thus the plasma potential V_{P} is relatively high and, hence, the effect of the sputtering on the sidewall of the chamber 10 increases on the average.

Since the in-phase mode and the anti-phase mode are the extreme cases, the effects of an intermediate mode between the two extreme modes can be obtained by appropriately varying the phase difference therebetween.

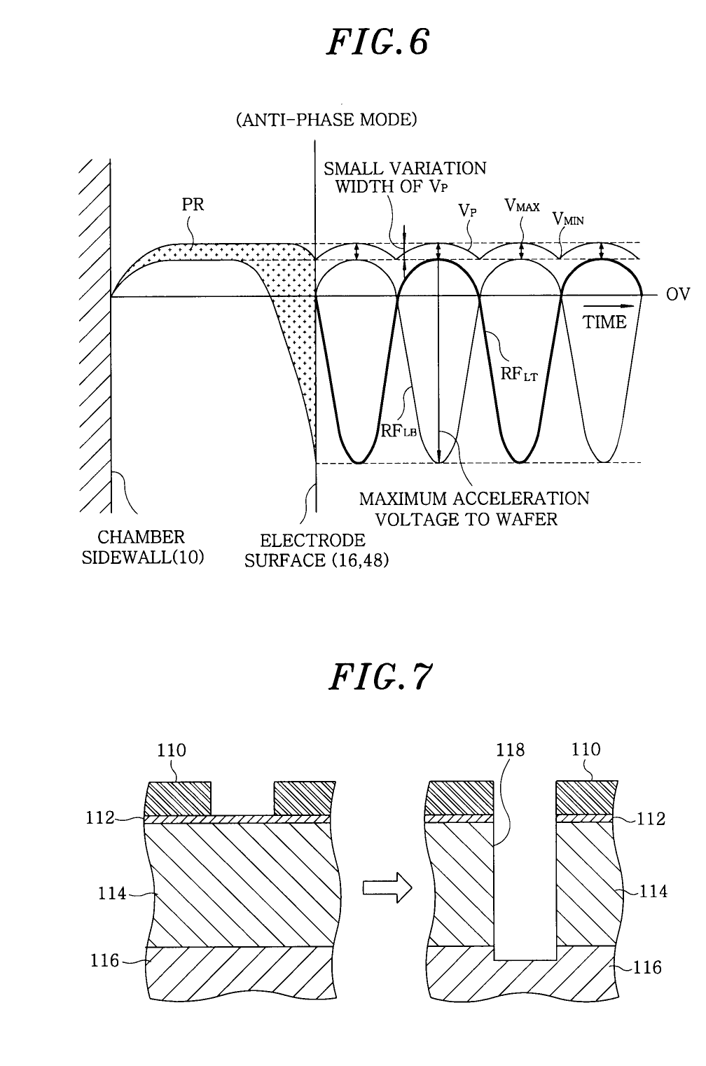

FIG. 7 shows an example to which a variable phase control of this embodiment can be applied. In this etching process, a via hole 118 is formed by consecutively etching an antireflection film 112, a silicon oxide film (SiO₂) 114 and an underlying film 116 in that order by multiple steps while using a resist 110 as a mask. The steps are carried out under different etching conditions. In such case, the phase difference between the upper electrode low frequency power RF_{LT} and the lower electrode low frequency power RF_{LB} can be included in one of the etching conditions and, also, the phase difference can be changed between the steps. However, to perform the etching with low ion energies in any of the steps, it is preferable to set the phase difference to a minimum value (in-phase) or a value close thereto. Then, the incident energy of ions to the semiconductor wafer W can be reduced.

Moreover, when the plasma cleaning is performed after unloading the processed semiconductor wafer W from the chamber 10 upon completion of the process, it is preferable to set the phase difference to a maximum value (anti-phase) or a value close thereto. Then, the plasma potential V_{P} increases, and the effect of the ion sputtering on the sidewall of the chamber 10 can be enhanced. As a result, the deposits can be effectively removed from the sidewall of the chamber 10 in a short period of time. Besides, when the deposits of an appropriate thickness need to be maintained to protect a base material of the sidewall of the chamber 10, the film thickness of the deposits can be optimally controlled simply by adjusting the phase difference.

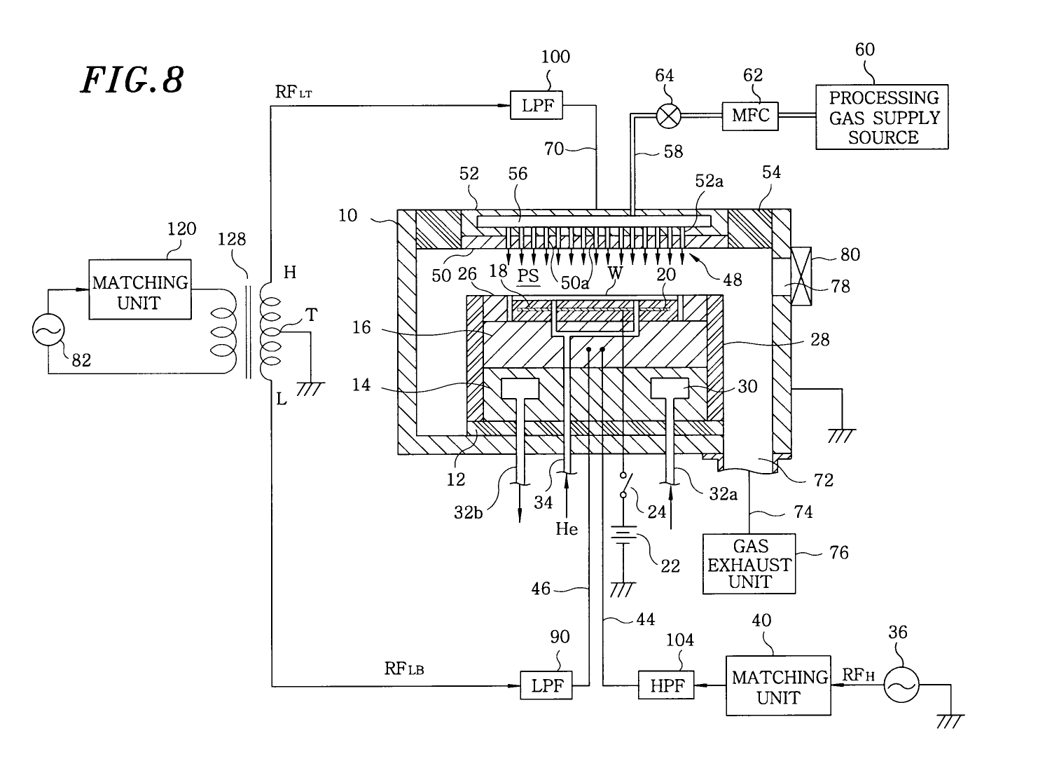

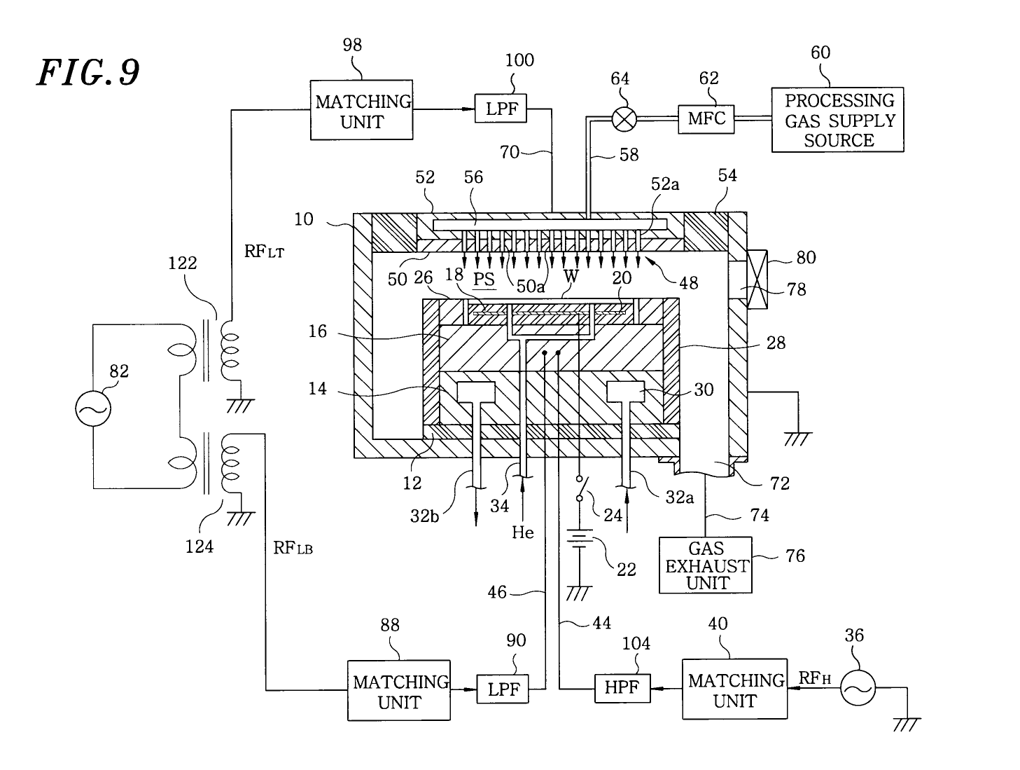

FIGS. 8 and 9 depict configurations of a first and a second modification of the second embodiment. In the configuration of FIG. 8, the low frequency power outputted from the low frequency power supply 82 is divided by a variable transformer 128 having a grounded center tap, so that the upper electrode low frequency power RF_{LT} and the lower electrode low frequency power RF_{LB} are applied in the anti-phase state from a secondary terminal of the transformer 128 to the upper electrode 48 and the lower electrode 16, respectively. In the transformer 128 of this configuration, the upper electrode low frequency power RF_{LT} relatively increases as the tap position T is close to an L side, whereas the lower electrode low frequency power RF_{LB} relatively increases as the tap position T is close to an H side. The matching unit 120 may be provided only at a primary side.

In the configuration of FIG. 9, the low frequency power from the low frequency power supply 82 is divided by two independent transformers 122 and 124, so that the upper electrode low frequency power RF_{LT} and the lower electrode low frequency power RF_{LB} are applied in the in-phase state from secondary terminals of the transformers 122 and 124 to the upper electrode 48 and the lower electrode 16, respectively.

In another embodiment that is not illustrated, the upper electrode low frequency power RF_{LT} can have a frequency higher than that of the lower electrode low frequency power RF_{LB} but lower than that of the lower electrode high frequency power RF_{H}. For example, RF_{LT} is 27 MHz; RF_{LB} is 3 MHZ; and RF_{H} is 40 MHz. In that case, the frequency of the upper electrode low frequency power RF_{LT} is relatively high, so that the self-bias voltage V_{DT} generated in the upper electrode 48 is reduced. Further, the positive ions in the plasma PR cannot respond to the RF electric field of the upper electrode low frequency power RF_{LT} and, thus, the ion sputtering on the upper electrode 48 becomes weak. On the other hand, the contribution of the upper electrode low frequency power RF_{LT} to the plasma generation increases, thereby improving the plasma density.

Besides, although it is not shown, in a modified example of the above embodiment, a high frequency power RF_{HT} having a frequency equal to that of the lower electrode high frequency power RF_{HB} can be applied to the upper electrode 48. For example, RF_{HT} is 40 MHz; RF_{LB} is 3.2 MHz; and RF_{HB} is 40 MHz. In that case, the ion sputtering on the upper electrode 48 is further reduced, whereas the plasma density is further improved.

In still another embodiment that is not illustrated, the low frequency power RF_{LB} and the high frequency power RF_{HB} can be superposedly applied to the lower electrode 16 and, also, the low frequency power RF_{LT} and the high frequency power RF_{HT} can be superposedly applied to the upper electrode 48. For example, RF_{LT} is 380 kHz; RF_{HT} is 60 MHz; RF_{LB} is 3.2 MHz; and RF_{HB} is 40 MHz. In this case, the plasma density can be improved and, also, the effect of the ion sputtering on the upper electrode 48 can be enhanced.

Moreover, in still another embodiment that is not shown, the high frequency power RF_{HB} as a single frequency is applied to the lower electrode 16 and, also, and the low frequency power RF_{LT} as a single frequency is applied to the upper electrode 48. For example, RF_{LT} is 380 kHz, and RF_{HB} is 40 MHz.

In the above embodiments, the frequencies of the low frequency powers and the high frequency powers applied to the upper electrode 48 and/or the lower electrode 16 can be varied or changed consecutively or step by step.

The present invention is not limited to the plasma etching, and can also be applied to other plasma processing such as plasma CVD, plasma oxidation, plasma nitrification, sputtering and the like. Further, as for a substrate, the present invention may use various substrates for plat panel display, a photomask, a CD substrate, a printed circuit board or the like other than a semiconductor wafer.

While the invention has been shown and described with respect to the embodiments, it will be understood by those skilled in the art that various changes and modification may be made without departing from the scope of the invention as defined in the following claims.

What is claimed is:

1. A plasma processing apparatus comprising:
a vacuum evacuable processing chamber;
a first electrode, attached to the processing chamber via an insulator, for supporting a substrate to be processed in the processing chamber;
a second electrode, attached to the processing chamber via an insulator, facing the first electrode in parallel in the processing chamber;
a processing gas supply unit for supplying a processing gas to a processing space between the first electrode and the second electrode;
a high frequency power supply unit for applying to the first electrode a high frequency power to generate a plasma of the processing gas in the processing space;
a first low frequency power supply unit for applying to the first electrode a first low frequency power to control energy of incident ions on the first electrode from the plasma, the frequency of the first low frequency power being lower than the frequency of the high frequency power; and
a second low frequency power supply unit for applying to the second electrode a second low frequency power to control energy of incident ions on the second electrode from the plasma, the frequency of the second low frequency power being lower than the frequency of the high frequency power.

2. The plasma processing apparatus of claim 1, wherein the frequency of the second low frequency power is lower than the frequency of the first low frequency power.

3. The plasma processing apparatus of claim 2, wherein the first low frequency power has a frequency higher than an ion plasma frequency and the second low frequency power has a frequency lower than the ion plasma frequency.

4. The plasma processing apparatus of claim 1, wherein the frequency of the second low frequency power equals to the frequency of the first low frequency power.

5. The plasma processing apparatus of claim 4, wherein the first and the second low frequency power supply unit share a common low frequency power supply.

6. The plasma processing apparatus of claim 5, wherein the first and the second low frequency power supply unit comprise a first and a second amplifier for amplifying the first and the second low frequency power, respectively.

7. The plasma processing apparatus of claim 5, wherein the first low frequency power supply unit comprises a first matching circuit for matching an impedance of a low frequency power supply side with an impedance of a first electrode side, and the second low frequency power supply unit comprises a second matching circuit for matching an impedance of a low frequency power supply side with an impedance of a second electrode side.

8. The plasma processing apparatus of claim 5, further comprising a phase control unit for varying a relative phase difference between the first low frequency power and the second low frequency power.

9. The plasma processing apparatus of claim 8, wherein when a plasma cleaning for removing a deposited film adhered to an inner wall of the processing chamber is performed, the phase difference is set to a maximum value or a value close thereto.

10. The plasma processing apparatus of claim 1, wherein the frequency of the second low frequency power is higher than the frequency of the first lower frequency power but lower than the frequency of the high frequency power.

11. A plasma processing apparatus comprising:
a vacuum evacuable processing chamber;
a first electrode, attached to the processing chamber via an insulator, for supporting a substrate to be processed in the processing chamber;
a second electrode, attached to the processing chamber via an insulator, facing the first electrode in parallel in the processing chamber;
a processing gas supply unit for supplying a processing gas to a processing space between the first electrode and the second electrode;
a first high frequency power supply unit for applying to the first electrode a first high frequency power to generate a plasma of the processing gas in the processing space;
a low frequency power supply unit for applying to the first electrode a low frequency power to control energy of incident ions on the first electrode from the plasma, the frequency of the low frequency power being lower than the frequency of the first high frequency power; and
a second high frequency power supply unit for applying to the second electrode a second high frequency power to control energy of incident ions on the second electrode from the plasma, the frequency of the second high frequency power being equaling to the frequency of the first high frequency power.

12. A plasma processing apparatus comprising:
a vacuum evacuable processing chamber;
a first electrode, attached to the processing chamber via an insulator, for supporting a substrate to be processed in the processing chamber;
a second electrode, attached to the processing chamber via an insulator, facing the first electrode in parallel in the processing chamber;
a processing gas supply unit for supplying a processing gas to a processing space between the first electrode and the second electrode;
a high frequency power supply unit for applying to the first electrode a high frequency power to generate a plasma of the processing gas in the processing space; and
a low frequency power supply unit for applying to the second electrode a low frequency power to control energy of incident ions on the second electrode from the plasma, the frequency of the low frequency power being lower than the frequency of the high frequency power.
